(19) United States
(12) Patent Application Publication
(10) Pub. No.: US 2017/0110178 A1
(43) Pub. Date: Apr. 20, 2017

(54) HYBRID REFRESH WITH HIDDEN REFRESHES AND EXTERNAL REFRESHES

(71) Applicant: Intel Corporation, Santa Clara, CA (US)

(72) Inventor: Kuljit S. BAINS, Olympia, WA (US)

(21) Appl. No.: 15/232,745

(22) Filed: Aug. 9, 2016

Related U.S. Application Data
(60) Provisional application No. 62/219,763, filed on Sep. 17, 2015.

(51) Int. Cl. G11C 11/406; G11C 11/4096; G06F 3/06; G11C 11/4093

(52) U.S. Cl. CPC G11C 11/40618; G11C 11/4093; G11C 11/4096; G06F 3/0619; G06F 3/0659; G06F 3/0683

(57) ABSTRACT

A memory subsystem enables satisfying refresh needs for a memory device with hidden refreshes performed by the memory device in response to Activate commands, and external refreshes to make up a difference between the number of hidden refreshes and a minimum number of total refreshes needed during a refresh window. With a hidden refresh the memory device executes the Activate command in one memory portion as indicated by the identified memory location of the command, and executes a refresh in a different portion, such as a different sub-bank. By combining external refreshes with hidden refreshes, the memory subsystem can enable hidden refreshes without the hidden refreshes causing a back-off or retry condition from the memory device to the memory controller.

### PRIORITY

The present application is a nonprovisional application based on U.S. Provisional Patent Application No. 62/219,763, filed Sep. 17, 2015, and claims the benefit of priority of that application.

### FIELD

The descriptions are generally related to memory devices, and more particular descriptions are related to memory device refresh.

### COPYRIGHT NOTICE/PERMISSION

Portions of the disclosure of this patent document may contain material that is subject to copyright protection. The copyright owner has no objection to the reproduction by anyone of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright© 2015, 2016, Intel Corporation, All Rights Reserved.

### BACKGROUND

Memory devices find ubiquitous use in electronic devices. Many electronic devices employ volatile memory devices, which provides a relatively large amount of storage space for a low cost, and provides faster access to data compared to spinning disk nonvolatile memory options. However, the volatile nature of volatile memory requires refreshing the memory devices to retain the data. Refreshing memory devices continues to take a large percentage of overall memory bandwidth, or bandwidth on a command bus between the memory controller and the memory devices. For example, with an 8 Giga bit (Gb) LPDDR3 (low power dual data rate, version 3) DRAM (dynamic random access memory) die can take up approximately 5.38% of overall bandwidth as a refresh command has to be sent every 3.9 microseconds (us) (tREFI, refresh interval time) and each refresh command takes 210 nanoseconds (ns) (tRFC, refresh cycle time or time between refresh commands) to complete (210 ns/3.9 us=5.38%). With 16 Gb devices the tRFC value is expected to almost double, which would indicate that future memory devices are at risk of using up more total bandwidth in refresh (e.g., approximately 10%). The more bandwidth a memory device uses in refresh, the less it has for processing data access commands (read or write), which can degrade memory subsystem performance.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a block diagram of an embodiment of a system with a memory device that supports hybrid refresh.

FIG. 2 is a block diagram of an embodiment of a system in which hybrid refresh combines internal hidden refresh with external refresh.

FIG. 3 is a block diagram of an embodiment of system illustrating possible hybrid refresh signaling.

FIG. 4A is a flow diagram of an embodiment of a process for performing hybrid refresh.

FIG. 4B is a flow diagram of an embodiment of a process for a memory controller to monitor refreshes.

FIG. 4C is a flow diagram of an embodiment of a process for a memory device to monitor refreshes.

FIG. 5 is a block diagram of an embodiment of a computing system in which hybrid refresh can be implemented.

FIG. 6 is a block diagram of an embodiment of a mobile device in which hybrid refresh can be implemented.

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, a memory subsystem enables satisfying refresh needs for a memory device with hidden refreshes performed by the memory device in response to Activate commands. A hidden refresh refers to a refresh executed by the memory device or DRAM (dynamic random access memory) device that is not directly in response to a refresh command by the memory controller. The system allows for external refreshes to make up a difference between the number of hidden refreshes and a minimum number of total refreshes needed during a refresh window. The refresh window refers to a refresh time or refresh period (e.g., tREF) that is the maximum or recommended time from one refresh of a row to another refresh of the row. The refresh window is dependent on the technology and architecture of the memory device, with some dual data rate (DDR) DRAM devices having a tREF equal to 64 milliseconds (ms) or 32 ms. The tREF is generally specified for a system, and delaying refresh of a row beyond tREF can affect the determinacy of data in the row of data. Thus, a system typically refreshes all rows within the refresh window. The number of refreshes required depends on the time of the refresh window, the refresh architecture (e.g., how many rows are refreshed in response to a single refresh command), and the total size of the memory array or how many rows need to be refreshed during the refresh window.

With a combination of hidden refreshes and explicit refresh commands, the system can allow for internal refreshes by the memory device to satisfy at least a portion of the refresh needs (without explicit refresh command bandwidth being used), and allow for external refresh in response to specific refresh commands from the memory controller to satisfy the remaining refresh needs. Thus, all refreshes needed to be completed can be accomplished within the refresh window by a combination of hidden internal refreshes and external refresh commands, where external refresh commands do not need to be relied on for all refresh operations. In one embodiment, with a hidden refresh, in response to an Activate command from the memory controller, the memory device execute the Activate in one sub-bank as indicated by the identified memory location of the command, and executes a refresh in a different sub-bank. By combining external refreshes with hidden refreshes, the memory subsystem can enable hidden refreshes without the hidden refreshes causing a back-off or retry condition from the memory device to the memory controller.

Existing proposals for hidden refresh require the memory controller to retry a transaction when the memory device is busy performing internal refreshes. Retrying transactions adds a lot of complexity to the memory controller in terms of pipelining commands and in replaying transactions. It also offsets some of the bandwidth savings by causing commands to be resent. Additionally, it will be understood that each memory device coupled to the memory controller performs internal refresh based on its own oscillator rather than based on a system timing signal from the memory controller. Memory device oscillators can vary noticeably over time, especially with respect to each other. When each memory device can separately request a retry due to performing internal refresh, if there are multiple memory devices on a rank coupled to the memory controller the probability of a retry increases.

Hybrid refresh can refer to the combination of internal refreshes hidden during the delay period (e.g., tRC or row cycle time) of an Activate command and external refreshes by the memory controller. In one embodiment, a memory device or DRAM performs hidden refresh by using an ACT (Activate command) as a trigger to refresh one or more sub-banks in the tRC window or tRC period. The tRC period is a required delay after an ACT command issued to a DRAM bank for certain memory device standards, such as those based on a dual data rate (DDR) technology (e.g., DDR4, DDR5, LPDDR4, LPDDR5, or extensions, or others). It will be understood that reference to a “refresh window” will generally refer to the period of time between refreshes (e.g., tREF), and the cycle time window refers to a delay imposed between accesses to the same row (e.g., tRC). If the DRAM needs more refreshes within the refresh window than can be accomplished through hidden refreshing, the memory controller or host controller can provide the additional refresh needs via external refresh commands. In one embodiment, the DRAM tracks the needed refreshes or additional refresh requirements and indicates those to the host controller. In one embodiment, the memory controller tracks additional refresh requirements. By having the memory controller provide external refreshes to satisfy the additional refresh requirements, the system can avoid the use of memory controller retries. As described herein, the memory devices do not rely only on internal hidden refresh, and so the memory devices will not issue busy signals to the memory controller due to refreshing when the memory controller tries to send an access command.

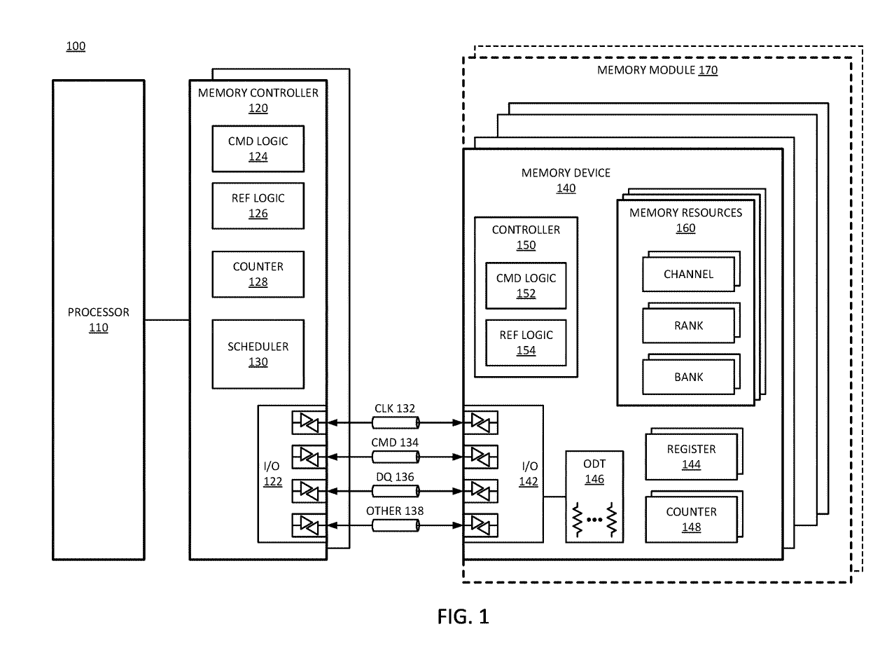

FIG. 1 is a block diagram of an embodiment of a memory subsystem in which an auxiliary memory controller utilizes high compressibility flags. System 100 includes a processor and elements of a memory subsystem in a computing device. Processor 110 represents a processing unit of a computing platform that may execute an operating system (OS) and applications, which can collectively be referred to as the “host,” which is the user of the memory. The OS and applications execute operations that result in memory accesses. Processor 110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or a hard disk controller. Such devices can be integrated with the processor in some systems or attached to the processor via a bus (e.g., PCI express), or a combination. System 100 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (dual data rate version 3, original release by JEDEC (Joint Electronic Device Engineering Council) on Jun. 27, 2007, currently on release 21), DDR4 (DDR version 4, initial specification published in September 2012 by JEDEC), DDR4E (DDR version 4, extended, currently in discussion by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (currently in discussion by JEDEC), HBM2 (HBM version 2), currently in discussion by JEDEC), or others or combinations of memory technologies, and technologies based on derivatives or extensions of such specifications.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint (3DXP) memory device, other byte addressable nonvolatile memory devices, or memory devices that use chalcogenide phase change material (e.g., chalcogenide glass). In one embodiment, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

Descriptions herein referring to a “DRAM” or “DRAM device” can apply to any memory device that allows random access, whether volatile or nonvolatile. The memory device or DRAM can refer to the die itself, to a packaged memory product that includes one or more dies, or both. Nonvolatile memory can be included in the same system with volatile memory that needs to be refreshed.

Memory controller 120 represents one or more memory controller circuits or devices for system 100. Memory controller 120 represents control logic that generates memory access commands in response to the execution of operations by processor 110. Memory controller 120 accesses one or more memory devices 140. Memory devices 140 can be DRAM devices in accordance with any referred to above. In one embodiment, memory devices 140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. As used herein, coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one embodiment, settings for each channel are controlled by separate mode registers or other register settings. In one embodiment, each memory controller 120 manages a separate memory channel, although system 100 can be configured to have multiple channels managed by a single controller, or to have multiple controllers on a single channel. In one embodiment, memory controller 120 is part of host processor 110, such as logic implemented on the same die or implemented in the same package space as the processor.

Memory controller 120 includes I/O interface logic 122 to couple to a memory bus, such as a memory channel as referred to above. I/O interface logic 122 (as well as I/O interface logic 142 of memory device 140) can include pins, pads, connectors, signal lines, traces, or wires, or other hardware to connect the devices, or a combination of these. I/O interface logic 122 can include a hardware interface. As illustrated, I/O interface logic 122 includes at least drivers/transceivers for signal lines. Commonly, wires within an integrated circuit interface couple with a pad, pin, or connector to interface signal lines or traces or other wires between devices. I/O interface logic 122 can include drivers, receivers, transceivers, or termination, or other circuitry or combinations of circuitry to exchange signals on the signal lines between the devices. The exchange of signals includes at least one of transmit or receive. While shown as coupling I/O 122 from memory controller 120 to I/O 142 of memory device 140, it will be understood that in an implementation of system 100 where groups of memory devices 140 are accessed in parallel, multiple memory devices can include I/O interfaces to the same interface of memory controller 120. In an implementation of system 100 including one or more memory modules 170, I/O 142 can include interface hardware of the memory module in addition to interface hardware on the memory device itself. Other memory controllers 120 will include separate interfaces to other memory devices 140.

The bus between memory controller 120 and memory devices 140 can be implemented as multiple signal lines coupling memory controller 120 to memory devices 140. The bus may typically include at least clock (CLK) 132, command/address (CMD) 134, and write data (DQ) and read DQ 136, and zero or more other signal lines 138. In one embodiment, a bus or connection between memory controller 120 and memory can be referred to as a memory bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one embodiment, independent channels have different clock signals, C/A buses, data buses, and other signal lines. Thus, system 100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 120 and memory devices 140. An example of a serial bus technology is 8B10B encoding and transmission of high-speed data with embedded clock over a single differential pair of signals in each direction.

It will be understood that in the example of system 100, the bus between memory controller 120 and memory devices 140 includes a subsidiary command bus CMD 134 and a subsidiary bus to carry the write and read data, DQ 136. In one embodiment, the data bus can include bidirectional lines for read data and for write/command data. In another embodiment, the subsidiary bus DQ 136 can include unidirectional write signal lines for write and data from the host to memory, and can include unidirectional lines for read data from the memory to the host. In accordance with the chosen memory technology and system design, the bus can be accompanied by other signals 138, such as strobe lines DQS. Based on design of system 100, or implementation if a design supports multiple implementations, the data bus can have more or less bandwidth per memory device 140. For example, the data bus can support memory devices that have either a x32 interface, a x16 interface, a x8 interface, or other interface. The convention “xW,” where W is a binary integer refers to an interface size or width of the interface of memory device 140, which represents a number of signal lines to exchange data with memory controller 120. The interface size of the memory devices is a controlling factor on how many memory devices can be used concurrently per channel in system 100 or coupled in parallel to the same signal lines.

Memory devices 140 represent memory resources for system 100. In one embodiment, each memory device 140 is a separate memory die. In one embodiment, each memory device 140 can interface with multiple (e.g., 2) channels per device or die. Each memory device 140 includes I/O interface logic 142, which has a bandwidth determined by the implementation of the device (e.g., x16 or x8 or some other interface bandwidth). I/O interface logic 142 enables the memory devices to interface with memory controller 120. I/O interface logic 142 can include a hardware interface, and can be in accordance with I/O 122 of memory controller, but at the memory device end. In one embodiment, multiple memory devices 140 are connected in parallel to the same command and data buses. In another embodiment, multiple memory devices 140 are connected in parallel to the same command bus, and are connected to different data buses. For example, system 100 can be configured with multiple memory devices 140 coupled in parallel, with each memory device responding to a command, and accessing memory resources 160 internal to each. For a Write operation, an individual memory device 140 can write a portion of the overall data word, and for a Read operation, an individual memory device 140 can fetch a portion of the overall data word.

In one embodiment, memory devices 140 are disposed directly on a motherboard or host system platform (e.g., a PCB (printed circuit board) on which processor 110 is disposed) of a computing device. In one embodiment, memory devices 140 can be organized into memory modules 170. In one embodiment, memory modules 170 represent dual inline memory modules (DIMM5). In one embodiment, memory modules 170 represent other organization of multiple memory devices to share at least a portion of access or control circuitry, which can be a separate circuit, a separate device, or a separate board from the host system platform. Memory modules 170 can include multiple memory devices 140, and the memory modules can include support for multiple separate channels to the included memory devices disposed on them. In another embodiment, memory devices 140 may be incorporated into the same package as memory controller 120, such as by techniques such as multi-chip-module (MCM), package-on-package, through-silicon VIA (TSV), or other techniques. Similarly, in another embodiment, multiple memory devices 140 may be incorporated into memory modules 170, which themselves may be incorporated into the same package as memory controller 120. It will be appreciated that for these and other embodiments, memory controller 120 may be part of host processor 110.

Memory devices 140 each include memory resources 160. Memory resources 160 represent individual arrays of memory locations or storage locations for data. Typically memory resources 160 are managed as rows of data, accessed via wordline (rows) and bitline (individual bits within a row) control. Memory resources 160 can be organized as separate channels, ranks, and banks of memory. Channels may refer to independent control paths to storage locations within memory devices 140. Ranks may refer to common locations across multiple memory devices (e.g., same row addresses within different devices). Banks may refer to arrays of memory locations within a memory device 140. In one embodiment, banks of memory are divided into sub-banks with at least a portion of shared circuitry (e.g., drivers, signal lines, control logic) for the sub-banks. It will be understood that channels, ranks, banks, sub-banks, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one embodiment, memory devices 140 include one or more registers 144. Register 144 represents one or more storage devices or storage locations that provide configuration or settings for the operation of the memory device. In one embodiment, register 144 can provide a storage location for memory device 140 to store data for access by memory controller 120 as part of a control or management operation. In one embodiment, register 144 includes one or more Mode Registers. In one embodiment, register 144 includes one or more multipurpose registers. The configuration of locations within register 144 can configure memory device 140 to operate in different “mode,” where command information can trigger different operations within memory device 140 based on the mode. Additionally or in the alternative, different modes can also trigger different operation from address information or other signal lines depending on the mode. Settings of register 144 can indicate configuration for I/O settings (e.g., timing, termination or ODT (on-die termination) 146, driver configuration, or other I/O settings).

In one embodiment, memory device 140 includes ODT 146 as part of the interface hardware associated with I/O 142. ODT 146 can be configured as mentioned above, and provide settings for impedance to be applied to the interface to specified signal lines. The ODT settings can be changed based on whether a memory device is a selected target of an access operation or a non-target device. ODT 146 settings can affect the timing and reflections of signaling on the terminated lines. Careful control over ODT 146 can enable higher-speed operation with improved matching of applied impedance and loading. ODT 146 can be applied to specific signal lines of I/O interface 142, 122, and is not necessarily applied to all signal lines.

Memory device 140 includes controller 150, which represents control logic within the memory device to control internal operations within the memory device. For example, controller 150 decodes commands sent by memory controller 120 and generates internal operations to execute or satisfy the commands. Controller 150 can be referred to as an internal controller, and is separate from memory controller 120 of the host. Controller 150 can determine what mode is selected based on register 144, and configure the internal execution of operations for access to memory resources 160 or other operations based on the selected mode. Controller 150 generates control signals to control the routing of bits within memory device 140 to provide a proper interface for the selected mode and direct a command to the proper memory locations or addresses.

Referring again to memory controller 120, memory controller 120 includes scheduler 130, which represents logic or circuitry to generate and order transactions to send to memory device 140. From one perspective, the primary function of memory controller 120 could be said to schedule memory access and other transactions to memory device 140. Such scheduling can include generating the transactions themselves to implement the requests for data by processor 110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 120 includes logic to allow selection and ordering of transactions to improve performance of system 100. Thus, memory controller 120 can select which of the outstanding transactions should be sent to memory device 140 in which order, which is typically achieved with logic much more complex that a simple first-in first-out algorithm. Memory controller 120 manages the transmission of the transactions to memory device 140, and manages the timing associated with the transaction. In one embodiment, transactions have deterministic timing, which can be managed by memory controller 120 and used in determining how to schedule the transactions.

Referring again to memory controller 120, memory controller 120 includes command (CMD) logic 124, which represents logic or circuitry to generate commands to send to memory devices 140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In one embodiment, controller 150 includes command logic 152 to receive and decode command and address information received via I/O 142 from memory controller 120. Based on the received command and address information, controller 150 can control the timing of operations of the logic and circuitry within memory device 140 to execute the commands. Controller 150 is responsible for compliance of timing and operations with standards or specifications internally within memory device 140. Memory controller 120 can implement compliance with standards or specifications by access scheduling and control.

In one embodiment, memory controller 120 includes refresh (REF) logic 126. Refresh logic 126 can be used for memory resources that are volatile and need to be refreshed to retain a deterministic state. In one embodiment, refresh logic 126 indicates a location for refresh, and a type of refresh to perform. Refresh logic 126 can trigger self-refresh within memory device 140, and/or execute external refreshes by sending refresh commands. For example, in one embodiment, system 100 supports all bank refreshes as well as per bank refreshes. All bank refreshes cause the refreshing of a selected bank within all memory devices 140 coupled in parallel. Per bank refreshes cause the refreshing of a specified bank within a specified memory device 140. In one embodiment, controller 150 within memory device 140 includes refresh logic 154 to apply refresh within memory device 140. In one embodiment, refresh logic 154 generates internal operations to perform refresh in accordance with an external refresh received from memory controller 120. Refresh logic 154 can determine if a refresh is directed to memory device 140, and what memory resources 160 to refresh in response to the command.

In one embodiment, system 100 supports hybrid refreshing. In a hybrid refresh, memory device 140 performs internal refreshes that are “hidden” from memory controller 120. Hidden refreshes are refreshes performed not in response to an external refresh command, but in response to another command. It will be understood that even self-refresh is a refresh command performed in response to an external refresh command, by memory controller 120 placing memory device 140 into self-refresh mode or self-refresh state. Hidden refresh is a refresh performed by memory device 140 in a delay period while waiting a defined window of time after initiating the execution of a command. For example, Activate commands have a defined window of time where the bank containing the memory location executing the Activate command is not available for other external commands. In one embodiment, refresh logic 154 triggers a refresh of a memory location of a different sub-bank when a memory location of one sub-bank is accessed by memory controller 120 with an Activate command. Thus, CMD logic 124 of memory controller 120 can generate and send, for example, an Activate command to memory device 140. In response to the Activate command, controller 150 of memory device 140 can cause CMD logic 152 to cause the execution of the Activate command at the specified bank, and cause refresh logic 154 to cause the execution of a refresh command at a different bank.

Alternative hidden refresh proposals include requiring a back-off or retry mechanism, where a memory device performing an internal refresh can indicate to the memory controller that it unavailable, requiring the memory controller to retry the transaction. With multiple memory devices on a rank (e.g., 4 or 8 DRAMs), the internal refreshes can easily become out of synchronization, since each memory device relies on an internal oscillator (not specifically shown) for internal refresh. If any memory device on a rank can request a retry at any time, the complexity to the memory controller is significant. Additionally, certain memory devices could execute the command and others request a retry, which increases the complexity. Hybrid refresh as described herein enables the use of hidden refreshes without triggering a retry of transactions.

In hidden refresh, a bank is open, for example, for tRC in response to each Activate command, and can perform a refresh on a different sub-bank within the bank during the tRC window. In one embodiment, in hybrid refresh, system 100 tracks how many external refreshes are needed to meet minimum refresh requirements for the bank in addition to the internal, hidden refreshes and other external refreshes have already been performed. System 100 can then perform external refreshes of a number at least sufficient to meet a minimum number of refreshes required within a refresh period (e.g., tREF). Thus, system 100 can allow memory devices 140 to perform hidden refreshes, and supplement the hidden refreshes with external refreshes sufficient to meet refresh requirements. For example, CMD logic 124 can generate Activate commands, and subsequently refresh logic 126 can send external refresh commands to make up for whatever memory resources were not refreshed with hidden refreshes. It will be understood that Activate commands are specifically referenced, as they are typically required to be issued prior to Read or Write commands. It will be understood that other commands can be the trigger for hidden refreshes, such as any command that includes a delay period that would allow access to another bank or sub-bank during the delay period.

In one embodiment, memory controller 120 tracks the number of external refreshes needed. In one embodiment, memory controller 120 includes one or more counters 128 to track the number of additional refreshes needed. For example, counter 128 can include per-bank counters to track the number of Activate commands sent to specific banks. In one embodiment, counter 128 counts the number of external refreshes that might already have been sent to the bank. In one embodiment, refresh logic 126 or other control logic within memory controller 120 determines, based on a number of Activate commands accumulated in counter 128 and a number of external refreshes accumulated in a different counter, how many additional external refreshes are needed. In one embodiment, memory controller 120 does not send any external refreshes until determining how many additional external refreshes are needed.

In one embodiment, memory device 140 tracks the number of external refreshes needed. In one embodiment, memory device 140 includes one or more counters 148 to track refreshes that have been performed internally to determine how many external refreshes are needed. In one embodiment, memory device 140 includes a counter 148 for each bank to accumulate refreshes for the bank. Alternatively, in one embodiment, counter 148 can be reset to a total number of needed refreshes within a refresh window, and counter 148 can decrement with each refresh performed. Thus, at a specified time, such as on a schedule, memory device 140 can indicate the number remaining in counter 148 to memory controller 120 to indicate how many external refreshes are needed.

In one embodiment, when memory device 140 tracks the number of additional refreshes needed, memory device 140 and memory controller 120 can engage in a “refresh handshake” or other comparable mechanism for the memory device to indicate the external refresh needs to the memory controller. For example, in one embodiment, memory device 140 stores a number of refreshes needed in register 144, and memory controller can be configured to read the register periodically. It will be understood that for a memory device with multiple banks, each bank can be at a different level of refresh during each refresh period. In one embodiment, memory device 140 indicates each bank's refresh needs separately. In one embodiment, memory controller 120 satisfies the refresh needs through per bank refresh commands (REFpb), all bank refresh commands (REF), or a combination.

Memory device 140 includes multiple portions of memory resources 160. For example, memory resources can include multiple banks of memory with multiple sub-banks each. Memory device 140 can receive an access command (e.g., an Activate command) directed to a specified memory location within one of the portions of memory, and execute the access command in the specified memory location, and also execute a hidden refresh at a memory location in a different portion (e.g., a different sub-bank of a first bank). Memory controller 120 can provide external refresh commands for the portion, where a total number of hidden refreshes and external refreshes are to satisfy a minimum number of total refreshes for the portion during a refresh window.

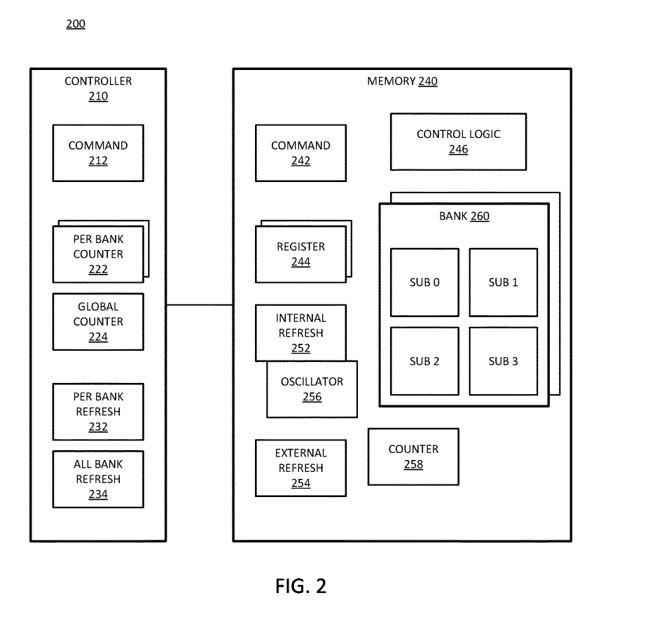

FIG. 2 is a block diagram of an embodiment of a system in which hybrid refresh combines internal hidden refresh with external refresh. System 200 provides one example of elements of a memory subsystem, and can be an example of elements of system 100 of FIG. 1. Controller 210 represents a memory controller or host controller. Memory 240 represents one or more memory devices of system 200, and can be, for example, one or more DRAMs or other memory devices or a group of memory devices.

In one embodiment, controller 210 includes command logic 212 to issues commands to memory 240. In one embodiment, controller 210 includes one or more per bank counters 222 per bank 260 of memory 240. In one embodiment, controller 210 can track the number of external refreshes needed to meet minimum refresh requirements for each bank with counters 222. In one embodiment, controller 210 includes global counter 224, which represents logic within controller 210 to determine how many all bank refreshes to issue to satisfy minimum refresh requirements for banks 260 of memory 240. In one embodiment, controller 210 includes per bank refresh logic 232 to issue per bank refreshes to memory 240. In one embodiment, controller 210 includes all bank refresh logic 234 to issue all bank refreshes to memory 240. Controller 210 can use refresh logic 232 and/or refresh logic 234 to issue external refreshes to satisfy additional refresh requirements not met by hidden refreshes within memory 240.

Memory 240 includes command logic 242, which represents logic to receive and decode commands from controller 210. Command logic 242 can be part of an on-die controller of memory 240. Memory 240 includes one or more registers 244, which represent storage locations within memory 240 where it can store values for access by controller 210, and/or where controller 210 can write values as configuration settings to control the operations of memory 240. Memory 240 includes banks 260, which represent memory resources managed as separate banks, or portions or separately addressable regions of memory address space. In one embodiment, each bank 260 is divided into multiple sub-banks. By way of example only, and not by way of limitation, banks 260 are shown having four sub-banks, Sub0, Sub1, Sub2, and Sub3. It will be understood that banks 260 can include a different number of sub-banks, such as 2, 6, 8, or other number. Typically the number of sub-banks will be a binary number, but it is not necessarily limited in this regard.

In one embodiment, memory 240 includes internal refresh logic 252, which enables it to perform refreshes internally. Internal refreshing can refer to the memory device performing one or more refresh operations initiated internally. The commands can be in response to an external command from controller 210, and not necessarily an external refresh command. It will be understood that memory 240 performs internal refresh operations in response to the external refresh command. As described herein, with internal refresh logic 252, memory 240 will not necessarily perform refreshes one-to-one based on external commands, and can perform refresh commands in response to receipt of one or more non-refresh commands. Internal refresh is controlled by an internal oscillator 256, which is different for each memory device on a rank, or channel, or DIMM, and the oscillators cannot be guaranteed to be in sync. External refresh logic 254 represents logic within memory 240 to execute refresh operations in response to external refresh commands from controller 210. In one embodiment, memory 240 includes one or more counters 258, which represent counter(s) to enable memory 240 to track a number of additional refreshes needed to satisfy refresh requirements.

In one embodiment, an ACT command triggers an internal refresh in one or more sub-arrays or sub-banks. In one embodiment, each bank includes multiple sub-arrays. The internal refresh by the DRAM or memory device can be performed in tRC or a row cycle time. The tRC window specifies the minimum time from an ACT to another access to a sub-array. In previous proposals, only internal refreshes were contemplated as a refresh solution. Whatever refreshes were not satisfied as part of hidden refreshes in parallel to ACT commands were satisfied by internal refreshes that could cause the DRAM to become unavailable for access by the memory controller. Thus, a memory controller could be required to wait until a DRAM was finished performing internal refresh before accessing the memory device. However, such unavailability becomes a significant issue when each DRAM could be separately, non-deterministically unavailable. Instead of performing all refreshes as internal refreshes, external refreshes from the memory controller can be combined with internal refreshes as a hybrid refresh technique.

In one embodiment, there are two general options that use a combination of DRAM generated refreshes and controller initiated refreshes, or hybrid refresh options. Both options can satisfy refresh requirements through hybrid refreshing without requiring any retry or back-off mechanisms. Generally the total number of refresh commands needed in a refresh window (e.g., a fixed 64 ms or 32 ms period) is defined by a standard, such as a DDR specification or other memory standard referred to above. In Option 1, the memory controller tracks the number of external refreshes needed. In Option 2, the memory device tracks the number of external refreshes needed.

In one embodiment, in Option 1, controller 210 counts the number of ACT commands issued and can issue external refresh commands for the remaining refresh commands needed. In one embodiment, controller 210 issues the external refreshes on a per bank basis. The total number of refresh commands may vary per supplier based on suppliers requirements on a given process node. The neighboring sub-arrays can potentially get starved out, as there is circuitry shared between neighboring sub-arrays. In one embodiment, controller 210 can track the needs and guarantee a minimum number of refresh commands in a refresh window based on the number of rows in the sub-arrays. In one embodiment, controller 210 can guarantee at least one refresh command every 9*tREFI to ensure row hammer free circuitry is not starved out.

In one embodiment, in Option 2, the DRAM devices track the number of refreshes needed, and the memory controller is not required to track the number of ACT commands. In one embodiment, memory 240 can track the number of actual refreshes it performs or executes in response to ACT commands, rather than requiring controller 210 to track ACT commands as a proxy for tracking the refreshes. In one embodiment, memory 240 sends an indicator that it needs additional refreshes to controller 210. Such an indicator can be sent with an external signal such as ALERT, with a MR (Mode Register) read command option, or a combination. In one embodiment, Mode Register contents can specify the number of refreshes needed in a certain rolling window. In one embodiment, a specification can dictate how often controller 210 is to read a register to determine how many external refreshes to issue. In one embodiment, the Mode Register can cover bank or bank group level granularity for systems using a per bank refresh feature. Option 2 allows flexibility in the implementation of the memory device, by allowing the system to issue external or additional refreshes needed based on process and temperature conditions, which can cause variation from device to device or system to system, or both.

With either Option 1 or Option 2, controller 210 can send, and in response to the sending memory 240 receives and executes, a number of external refreshes necessary to satisfy the minimum number of total refreshes for the refresh period. In one embodiment, controller 210 can send one or more per bank refreshes for the external refresh commands. In one embodiment, controller 210 can send one or more all bank refreshes for the external refresh commands.

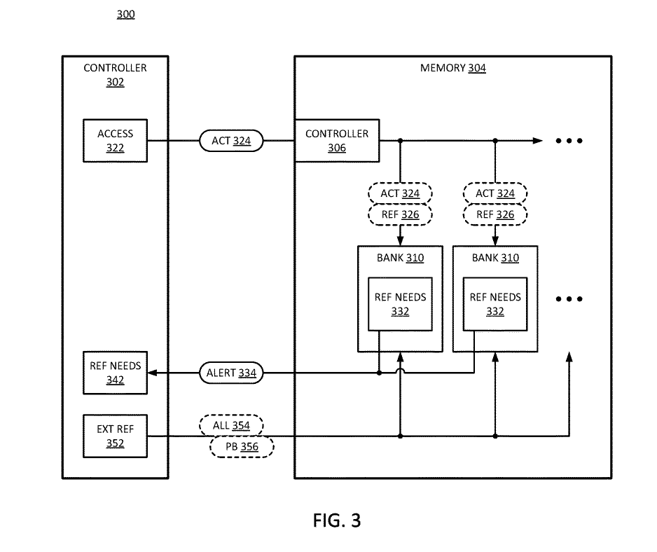

FIG. 3 is a block diagram of an embodiment of system illustrating possible hybrid refresh signaling. System 300 provides one example of elements of a memory subsystem, and can be in accordance with one embodiment of system 200 of FIG. 2 and/or in accordance with one embodiment of system 100 of FIG. 1. Controller 302 represents a host controller or a memory controller. Memory 304 represents one or more memory devices or DRAMs.

In one embodiment, controller 302 includes access logic 322, which generates ACT command 324 to memory 304. ACT 324 can be directed to a specific memory location, which can be within a specific bank and sub-bank of memory 304. In one embodiment, on-die controller 306 of memory 304 receives and decodes ACT 324, and generates one or more internal operations to execute the command. As illustrated, controller 306 can route the command operations to the appropriate target bank 310. Typically only one bank 310 will be the target bank. The dashed lines show the possibility of sending commands to any of the banks as the target bank, based on the address of ACT 324. In one embodiment, in addition to generating internal operations to execute ACT 324, controller 306 also generates one or more hidden refresh commands, REF 326, to execute a different portion of memory 304. In one embodiment, the different portion of memory 304 is a different sub-bank of the target bank during the ACT delay window. Thus, in one embodiment, both ACT 324 and REF 326 can be sent to the same bank 310, with ACT 324 directed to one sub-bank, and REF 326 directed to a different sub-bank.

In one embodiment, memory 304 tracks internal REF 326 command issued for each bank 310, and determines individually for each bank 310 what its additional refresh requirements are. The additional refresh requirements are represented within each bank 310 as REF needs 332. REF needs 332 can be different for each bank, since a different number of ACT commands will be issued to each bank in operation of system 300. In one embodiment, memory 304 provides REF needs 332 to controller 302, for example, by storing the values in one or more registers (not specifically shown) for access by controller 302. In one embodiment, memory 304 triggers an alert signal Alert 334 to indicate to controller 302 that the values are ready to be read and used.

In one embodiment, controller 302 determines REF needs 342 via reading a register in response to an alert by memory 304. In one embodiment, controller 302 determines REF needs 342 via tracking internally in the memory controller how many refreshes are needed by each bank 310. In such an embodiment, memory 304 would not necessarily track REF needs 332. External refresh (EXT REF) 352 represents logic within controller 302 to issue external refreshes to satisfy REF needs 342 (in response to internal tracking) or REF needs 332 (in response to tracking by memory 304). In one embodiment, external refresh logic 352 issues one or more all bank refreshes (ALL) 354, or one or more per bank refreshes (PB) 356, or both, to banks 310. All bank refreshes 354 triggers all banks 310 to perform refresh. Per bank refreshes 356 trigger an individually-specified bank 310 to perform a refresh. The combination of hidden REF 326, plus a combination of ALL 354, or PB 356, or both, should meet a minimum refresh requirement for memory 304 within a refresh period. Thus, controller 302 can issue a combination of ALL 354 and PB 356 to make up a difference between REF 326 for each bank and a refresh requirement for the refresh period.

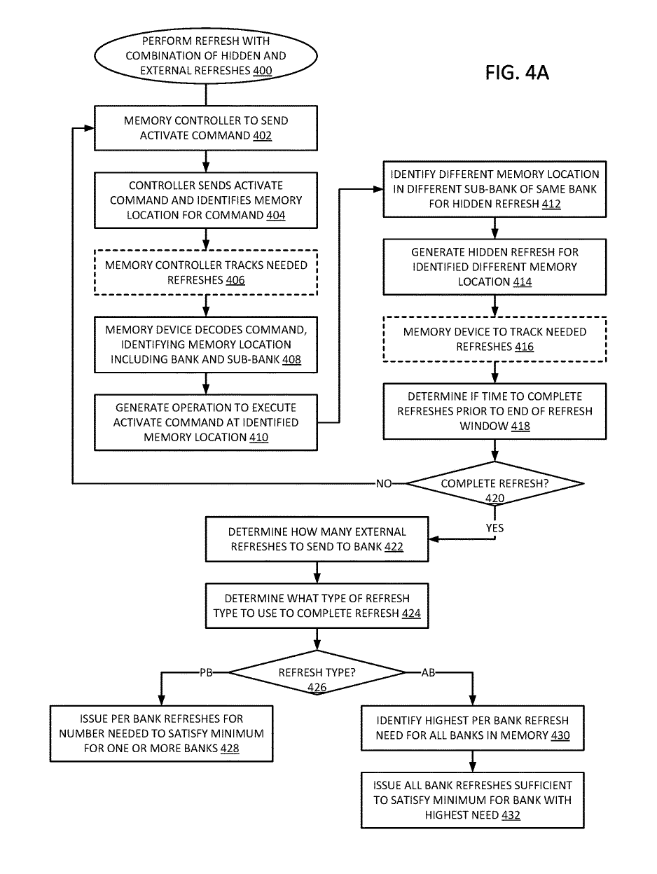

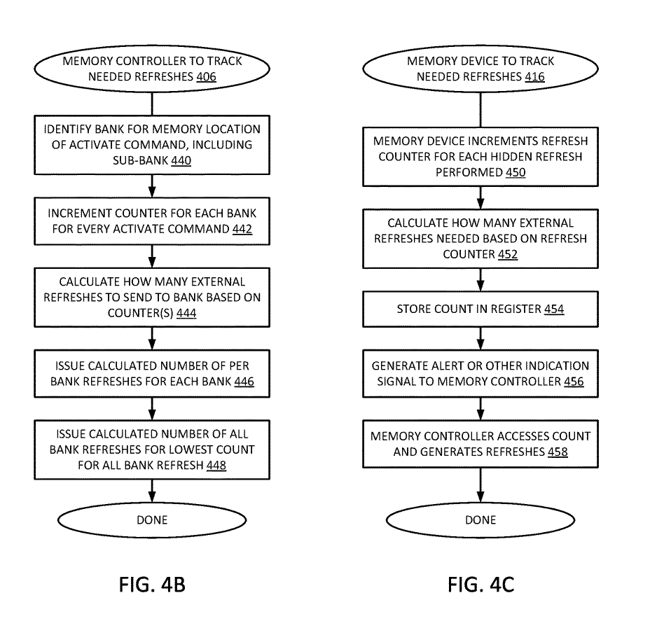

FIG. 4A is a flow diagram of an embodiment of a process for performing hybrid refresh. Process 400 describes operations to provide refreshes for one or more banks of memory with a combination of hidden, internal refreshes and external refreshes. Process 300 can execute within any of systems 100, 200, or 300. In one embodiment, the memory device performs hidden refreshes internally in response to an Activate command sent by the memory controller. The memory controller can send the Activate command as part of a memory access (e.g., Read or Write) or memory management operation, 402. When sending the Activate command, the memory controller can identify the target memory location for the command, 404. In one embodiment, as described in more detail below with respect to FIG. 4B, the memory controller can track the refreshes needed for a bank, 406, based on the number of Activate commands it issues to each bank or other portion of memory.

In one embodiment, in response to receiving an Activate command, the memory device decodes the command, including identifying the target memory location for execution of the command, 408. Identifying the target memory location can include identifying a bank and sub-bank associated with the memory location. An internal controller of the memory device generates one or more operations to execute the Activate command at the identified memory location, 410. In one embodiment, the internal controller also identifies a different memory location, such as a different sub-bank of the same bank, to perform a hidden refresh, 412. Thus, the memory device can identify a memory location to refresh in a different portion during the delay associated with performing the Activate command in the target memory location. Since the specific bank will already be busy based on the Activate command, refresh to a different sub-bank provides for efficiency. In one embodiment, logic within the memory device generates one or more operations for a hidden refresh at the different memory location, 414. In one embodiment, as described in more detail below with respect to FIG. 4C, the memory device can track the refreshes needed for a bank, 416, based on the number of hidden refreshes it generates for each portion of memory.

In one embodiment, the memory subsystem, either the memory controller, or the memory device, or both, determine if it is time to complete refreshes prior to the refresh window (e.g., 32 ms or 64 ms), 418. In one embodiment, determination of whether it is time to complete refresh can include a determination of how many refreshes are still needed, and how long it would take to complete the refreshes. Thus, in one embodiment, the memory controller or the memory device or both can determine based on the amount of time left in the refresh window and the number of refreshes needed, when external refreshes should begin to be executed. If it is not time to complete refreshes, 420 NO branch, the memory controller can continue to perform memory access to the memory device, including sending Activate commands, 402. The number of Activates and hidden refreshes can accumulate until a time when refreshes will need to be performed to satisfy minimum requirements for the device.

If it is time to complete the refreshes, 420 YES branch, the memory controller or memory device, depending on which is tracking the number of needed refreshes, can determine how many external refreshes need to be sent to each bank, 422. In one embodiment, whether the memory controller or memory device calculates how many refreshes are needed for each bank, the memory controller will determine how many refreshes are needed, either through its own detection, or through receiving an indication from the memory device. The memory controller will determine what type and how many of each type of refresh to use to complete the refreshes, 424. In one embodiment, the memory controller determines to issue per bank refreshes, 426 PB branch, and issues per bank refreshes for a number needed to satisfy the minimum number for each bank, 428. In one embodiment, the memory controller determines to issue all bank refreshes, 428 AB branch, and identifies a bank with the highest need for refreshes within the banks of the memory device, 430. The memory controller can then issue a number of all bank refreshes sufficient to satisfy the minimum number of refreshes for the bank with the highest need, 432.

In one embodiment, a more intelligent, more flexible refresh can be operated to meet minimum needs. For example, the memory controller can identify which bank has the lowest number of refreshes needed, instead of the highest number as mentioned above. In one embodiment, the memory controller issues a number of all bank refreshes necessary to satisfy the refresh needs of the bank with the lowest need. But seeing that the other banks need more refreshes, it can be an efficient use of bandwidth to refresh all banks for the lowest number of times. The memory controller can then satisfy the needs of the other banks by issuing per bank refreshes to individual banks. Other combinations of per bank and all bank refreshes are possible.

FIG. 4B is a flow diagram of an embodiment of a process for a memory controller to monitor or track refresh needs. Process 406 describes operations for one embodiment of the memory controller tracking the needed refreshes for the banks, as part of process 400 of FIG. 4A. In one embodiment, the memory controller identifies a bank for the target memory location of an Activate command, including identifying the sub-bank, 440. In one embodiment, the memory controller includes one or more counters to track Activate commands. In one embodiment, the memory controller includes at least one counter for each bank. Thus, the memory controller can increment a counter for each Activate command for each bank, 442.

In one embodiment, the memory controller calculates how many external refreshes to send to each bank based at least in part on the counter(s), 444. In one embodiment, the memory controller satisfies refresh needs through per bank refreshes. Thus, in one embodiment, the memory controller issues the calculated number of per bank refreshes to refresh each bank, 446. In one embodiment, the memory controller satisfies refresh needs through all bank refreshes. Thus, in one embodiment, the memory controller calculates a number of all bank refreshes needed for the highest need for refreshes (meaning the lowest Activate commands were counted) for all banks, 448. In one embodiment, the memory controller satisfies refresh need through a combination of all bank and per bank external refreshes.

FIG. 4C is a flow diagram of an embodiment of a process for a memory device to monitor or track refresh needs. Process 416 describes operations for one embodiment of the memory device tracking the needed refreshes for the banks, as part of process 400 of FIG. 4A. In one embodiment, the memory device increments a refresh counter for each hidden refresh performed, 450. In one embodiment, the memory device calculates how many external refreshes are needed based on the refresh counter for each bank, 452.

In one embodiment, the memory device stores the refresh need as a value in a register, 454, such as a mode register or multipurpose register. The register can hold values for each bank. In one embodiment, the memory device generates an alert or other indication signal to the memory controller, 456. In one embodiment, the memory controller accesses the count or counts from the register and generates refreshes to satisfy the refresh needs of each bank, 458. In one embodiment, the memory controller satisfies the refresh needs of each bank through all bank refreshes, per bank refreshes, or a combination.

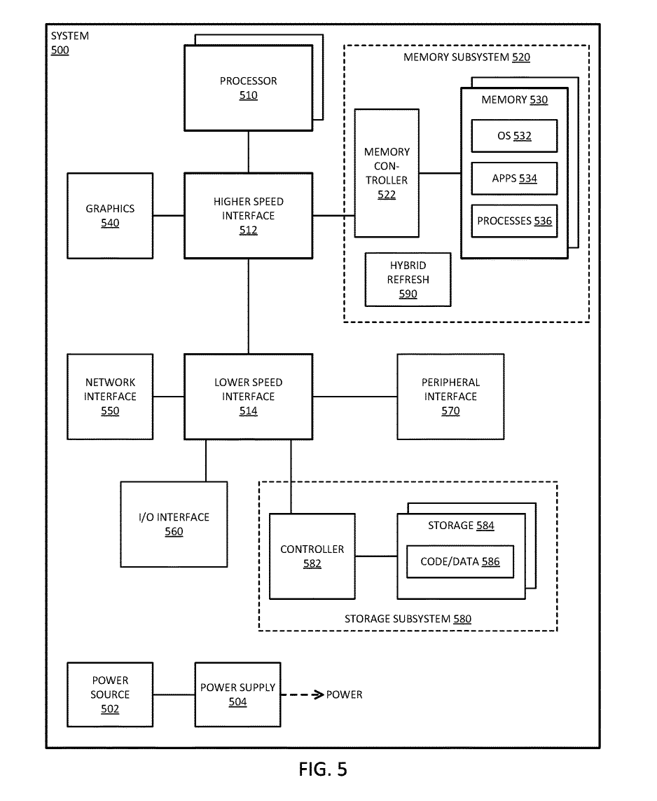

FIG. 5 is a block diagram of an embodiment of a computing system in which hybrid refresh can be implemented. System 500 represents a computing device in accordance with any embodiment described herein, and can be a laptop computer, a desktop computer, a tablet computer, a server, a gaming or entertainment control system, a scanner, copier, printer, routing or switching device, embedded computing device, a smartphone, a wearable device, an internet-of-things device or other electronic device.

System 500 includes processor 510, which provides processing, operation management, and execution of instructions for system 500. Processor 510 can include any type of microprocessor, central processing unit (CPU), graphics processing unit (GPU), processing core, or other processing hardware to provide processing for system 500, or a combination of processors. Processor 510 controls the overall operation of system 500, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one embodiment, system 500 includes interface 512 coupled to processor 510, which can represent a higher speed interface or a high throughput interface for system components that needs higher bandwidth connections, such as memory subsystem 520 or graphics interface components 540. Interface 512 can represent a “north bridge” circuit, which can be a standalone component or integrated onto a processor die. Where present, graphics interface 540 interfaces to graphics components for providing a visual display to a user of system 500. In one embodiment, graphics interface 540 generates a display based on data stored in memory 530 or based on operations executed by processor 510 or both.

Memory subsystem 520 represents the main memory of system 500, and provides storage for code to be executed by processor 510, or data values to be used in executing a routine. Memory subsystem 520 can include one or more memory devices 530 such as read-only memory (ROM), flash memory, one or more varieties of random access memory (RAM) such as DRAM, or other memory devices, or a combination of such devices. Memory 530 stores and hosts, among other things, operating system (OS) 532 to provide a software platform for execution of instructions in system 500. Additionally, applications 534 can execute on the software platform of OS 532 from memory 530. Applications 534 represent programs that have their own operational logic to perform execution of one or more functions. Processes 536 represent agents or routines that provide auxiliary functions to OS 532 or one or more applications 534 or a combination. OS 532, applications 534, and processes 536 provide software logic to provide functions for system 500. In one embodiment, memory subsystem 520 includes memory controller 522, which is a memory controller to generate and issue commands to memory 530. It will be understood that memory controller 522 could be a physical part of processor 510 or a physical part of interface 512. For example, memory controller 522 can be an integrated memory controller, integrated onto a circuit with processor 510.

While not specifically illustrated, it will be understood that system 500 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”).

In one embodiment, system 500 includes interface 514, which can be coupled to interface 512. Interface 514 can be a lower speed interface than interface 512. In one embodiment, interface 514 can be a “south bridge” circuit, which can include standalone components and integrated circuitry. In one embodiment, multiple user interface components or peripheral components, or both, couple to interface 514. Network interface 550 provides system 500 the ability to communicate with remote devices (e.g., servers or other computing devices) over one or more networks. Network interface 550 can include an Ethernet adapter, wireless interconnection components, cellular network interconnection components, USB (universal serial bus), or other wired or wireless standards-based or proprietary interfaces. Network interface 550 can exchange data with a remote device, which can include sending data stored in memory or receiving data to be stored in memory.

In one embodiment, system 500 includes one or more input/output (I/O) interface(s) 560. I/O interface 560 can include one or more interface components through which a user interacts with system 500 (e.g., audio, alphanumeric, tactile/touch, or other interfacing). Peripheral interface 570 can include any hardware interface not specifically mentioned above. Peripherals refer generally to devices that connect dependently to system 500. A dependent connection is one where system 500 provides the software platform or hardware platform or both on which operation executes, and with which a user interacts.

In one embodiment, system 500 includes storage subsystem 580 to store data in a nonvolatile manner. In one embodiment, in certain system implementations, at least certain components of storage 580 can overlap with components of memory subsystem 520. Storage subsystem 580 includes storage device(s) 584, which can be or include any conventional medium for storing large amounts of data in a nonvolatile manner, such as one or more magnetic, solid state, or optical based disks, or a combination. Storage 584 holds code or instructions and data 586 in a persistent state (i.e., the value is retained despite interruption of power to system 500). Storage 584 can be generically considered to be a “memory,” although memory 530 is typically the executing or operating memory to provide instructions to processor 510. Whereas storage 584 is nonvolatile, memory 530 can include volatile memory (i.e., the value or state of the data is indeterminate if power is interrupted to system 500). In one embodiment, storage subsystem 580 includes controller 582 to interface with storage 584. In one embodiment controller 582 is a physical part of interface 514 or processor 510, or can include circuits or logic in both processor 510 and interface 514.

Power source 502 provides power to the components of system 500. More specifically, power source 502 typically interfaces to one or multiple power supplies 504 in system 502 to provide power to the components of system 500. In one embodiment, power supply 504 includes an AC to DC (alternating current to direct current) adapter to plug into a wall outlet. Such AC power can be renewable energy (e.g., solar power) power source 502. In one embodiment, power source 502 includes a DC power source, such as an external AC to DC converter. In one embodiment, power source 502 or power supply 504 includes wireless charging hardware to charge via proximity to a charging field. In one embodiment, power source 502 can include an internal battery or fuel cell source.

In one embodiment, system 500 includes hybrid refresh logic 590, which enables the system to satisfy refresh needs within memory 530 via a combination of hidden refreshes and external refreshes, in accordance with any embodiment described herein. Memory 530 or memory controller 522 or both can track the number of hidden refreshes performed by memory 530 in response to Activate commands. Based on the number of hidden refreshes performed, memory 530 or memory controller 522 or both can determine how many refreshes are needed by each bank to satisfy a minimum requirement within a refresh window. Memory controller 522 can issue external refreshes to satisfy the minimum requirement. The memory controller can issue per bank refreshes, all bank refreshes, or both to refresh the banks.

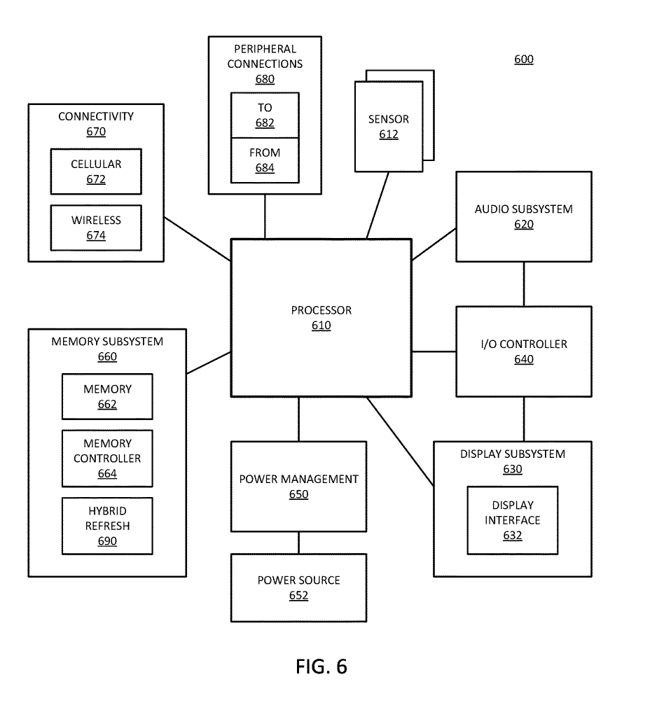

FIG. 6 is a block diagram of an embodiment of a mobile device in which hybrid refresh can be implemented. Device 600 represents a mobile computing device, such as a computing tablet, a mobile phone or smartphone, a wireless-enabled e-reader, wearable computing device, an internet-of-things device or other mobile device, or an embedded computing device. It will be understood that certain of the components are shown generally, and not all components of such a device are shown in device 600.

Device 600 includes processor 610, which performs the primary processing operations of device 600. Processor 610 can include one or more physical devices, such as microprocessors, application processors, microcontrollers, programmable logic devices, or other processing means. The processing operations performed by processor 610 include the execution of an operating platform or operating system on which applications and device functions are executed. The processing operations include operations related to I/O (input/output) with a human user or with other devices, operations related to power management, operations related to connecting device 600 to another device, or a combination. The processing operations can also include operations related to audio I/O, display I/O, or other interfacing, or a combination. Processor 610 can execute data stored in memory. Processor 610 can write or edit data stored in memory.

In one embodiment, system 600 includes one or more sensors 612. Sensors 612 represent embedded sensors or interfaces to external sensors, or a combination. Sensors 612 enable system 600 to monitor or detect one or more conditions of an environment or a device in which system 600 is implemented. Sensors 612 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 612 can also include sensors for biometric systems such as fingerprint recognition systems, face detection or recognition systems, or other systems that detect or recognize user features. Sensors 612 should be understood broadly, and not limiting on the many different types of sensors that could be implemented with system 600. In one embodiment, one or more sensors 612 couples to processor 610 via a frontend circuit integrated with processor 610. In one embodiment, one or more sensors 612 couples to processor 610 via another component of system 600.

In one embodiment, device 600 includes audio subsystem 620, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into device 600, or connected to device 600. In one embodiment, a user interacts with device 600 by providing audio commands that are received and processed by processor 610.

Display subsystem 630 represents hardware (e.g., display devices) and software components (e.g., drivers) that provide a visual display for presentation to a user. In one embodiment, the display includes tactile components or touchscreen elements for a user to interact with the computing device. Display subsystem 630 includes display interface 632, which includes the particular screen or hardware device used to provide a display to a user. In one embodiment, display interface 632 includes logic separate from processor 610 (such as a graphics processor) to perform at least some processing related to the display. In one embodiment, display subsystem 630 includes a touchscreen device that provides both output and input to a user. In one embodiment, display subsystem 630 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. In one embodiment, display subsystem 630 generates display information based on data stored in memory and operations executed by processor 610.

I/O controller 640 represents hardware devices and software components related to interaction with a user. I/O controller 640 can operate to manage hardware that is part of audio subsystem 620, or display subsystem 630, or both. Additionally, I/O controller 640 illustrates a connection point for additional devices that connect to device 600 through which a user might interact with the system. For example, devices that can be attached to device 600 might include microphone devices, speaker or stereo systems, video systems or other display device, keyboard or keypad devices, or other I/O devices for use with specific applications such as card readers or other devices.

As mentioned above, I/O controller 640 can interact with audio subsystem 620 or display subsystem 630 or both. For example, input through a microphone or other audio device can provide input or commands for one or more applications or functions of device 600. Additionally, audio output can be provided instead of or in addition to display output. In another example, if display subsystem includes a touchscreen, the display device also acts as an input device, which can be at least partially managed by I/O controller 640. There can also be additional buttons or switches on device 600 to provide I/O functions managed by I/O controller 640.

In one embodiment, I/O controller 640 manages devices such as accelerometers, cameras, light sensors or other environmental sensors, gyroscopes, global positioning system (GPS), or other hardware that can be included in device 600, or sensors 612. The input can be part of direct user interaction, as well as providing environmental input to the system to influence its operations (such as filtering for noise, adjusting displays for brightness detection, applying a flash for a camera, or other features).

In one embodiment, device 600 includes power management 650 that manages battery power usage, charging of the battery, and features related to power saving operation. Power management 650 manages power from power source 652, which provides power to the components of system 600. In one embodiment, power source 652 includes an AC to DC (alternating current to direct current) adapter to plug into a wall outlet. Such AC power can be renewable energy (e.g., solar power, motion based power). In one embodiment, power source 652 includes only DC power, which can be provided by a DC power source, such as an external AC to DC converter. In one embodiment, power source 652 includes wireless charging hardware to charge via proximity to a charging field. In one embodiment, power source 652 can include an internal battery or fuel cell source.

Memory subsystem 660 includes memory device(s) 662 for storing information in device 600. Memory subsystem 660 can include nonvolatile (state does not change if power to the memory device is interrupted) or volatile (state is indeterminate if power to the memory device is interrupted) memory devices, or a combination. Memory 660 can store application data, user data, music, photos, documents, or other data, as well as system data (whether long-term or temporary) related to the execution of the applications and functions of system 600. In one embodiment, memory subsystem 660 includes memory controller 664 (which could also be considered part of the control of system 600, and could potentially be considered part of processor 610). Memory controller 664 includes a scheduler to generate and issue commands to memory device 662.

Connectivity 670 includes hardware devices (e.g., wireless or wired connectors and communication hardware, or a combination of wired and wireless hardware) and software components (e.g., drivers, protocol stacks) to enable device 600 to communicate with external devices. The external device could be separate devices, such as other computing devices, wireless access points or base stations, as well as peripherals such as headsets, printers, or other devices. In one embodiment, system 600 exchanges data with an external device for storage in memory or for display on a display device. The exchanged data can include data to be stored in memory, or data already stored in memory, to read, write, or edit data.

Connectivity 670 can include multiple different types of connectivity. To generalize, device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 674 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 680 include hardware interfaces and connectors, as well as software components (e.g., drivers, protocol stacks) to make peripheral connections. It will be understood that device 600 could both be a peripheral device (“to” 682) to other computing devices, as well as have peripheral devices (“from” 684) connected to it. Device 600 commonly has a “docking” connector to connect to other computing devices for purposes such as managing (e.g., downloading, uploading, changing, synchronizing) content on device 600. Additionally, a docking connector can allow device 600 to connect to certain peripherals that allow device 600 to control content output, for example, to audiovisual or other systems.

In addition to a proprietary docking connector or other proprietary connection hardware, device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one embodiment, system 600 includes hybrid refresh logic 690, which enables the system to satisfy refresh needs within memory 662 via a combination of hidden refreshes and external refreshes, in accordance with any embodiment described herein. Memory 662 or memory controller 664 or both can track the number of hidden refreshes performed by memory 662 in response to Activate commands. Based on the number of hidden refreshes performed, memory 662 or memory controller 664 or both can determine how many refreshes are needed by each bank to satisfy a minimum requirement within a refresh window. Memory controller 664 can issue external refreshes to satisfy the minimum requirement. The memory controller can issue per bank refreshes, all bank refreshes, or both to refresh the banks.

In one aspect, a memory device to interface in a memory subsystem includes: a first of multiple portions of memory; I/O (input/output) hardware to couple to an associated memory controller, and receive commands from the memory controller, including Activate commands directed to specified memory locations within the first portion; and control logic internal to the memory device, responsive to receipt of an Activate command, to execute the Activate command at a specified memory location of the first portion, and to execute a hidden refresh at a memory location in a second portion different from the first portion; wherein the control logic to further execute external refreshes from the memory controller for the first portion, where a total number of hidden refreshes and external refreshes are to satisfy a minimum number of total refreshes for the first portion during a refresh window.

In one embodiment, the refresh window comprises a refresh cycle time. In one embodiment, the I/O hardware is to receive a number of external refreshes necessary to satisfy the minimum number of total refreshes after a determination of how many external refreshes are needed to satisfy the minimum number of total refreshes. In one embodiment, the external refreshes include per bank refreshes. In one embodiment, the external refreshes include all bank refreshes. In one embodiment, the control logic is to determine how many external refreshes are needed. In one embodiment, the I/O hardware is to provide an indication of the number of external refreshes needed to the memory controller. In one embodiment, further comprising a register, wherein the control logic is to store the number of external refreshes in the register for access by the memory controller. In one embodiment, the memory controller is to determine how many external refreshes are needed. In one embodiment, the memory controller is to detect a number of Activate commands sent to respective portions, and to determine a number of external refreshes needed for the first portion to satisfy the minimum number of total refreshes based on the number of Activates sent to the first portion. In one embodiment, the portion comprises a bank, and wherein the memory controller includes per bank counters to detect a number of Activate commands sent to respective banks, and to send a number of all bank refreshes based on a lowest count of the per bank counters. In one embodiment, the first portion comprises a first bank of multiple banks of memory. In one embodiment, the first bank includes multiple sub-banks, and wherein the control logic is to execute the hidden refresh at a memory location of a different sub-bank of the first bank. In one embodiment, the memory device comprises a synchronous dynamic random access memory (SDRAM) device compatible with a dual data rate version 5 (DDR5) based standard. In one embodiment, the memory device comprises a synchronous dynamic random access memory (SDRAM) device compatible with a low power dual data rate version 5 (LPDDR5) based standard.

In one aspect, a system for memory management includes: a memory device including multiple banks, including a first of multiple portions of memory; and control logic; and a memory controller to issue commands to the memory device, including Activate commands directed to specified memory locations within the first portion; wherein, responsive to receipt of an Activate command, the control logic of the memory device to execute the Activate command at a specified memory location of the first portion, and to execute a hidden refresh at a memory location in a second portion different from the first portion; and wherein the control logic to further execute external refreshes from the memory controller for the first portion, where a total number of hidden refreshes and external refreshes are to satisfy a minimum number of total refreshes for the first portion during a refresh window.

The system of the preceding system can include any embodiment of the preceding memory device. In one embodiment, further comprising one or more of: at least one processor communicatively coupled to the memory controller and the memory device; a display communicatively coupled to at least one processor; a battery to power the system; or a network interface communicatively coupled to at least one processor.

In one aspect, a method for refreshing a memory device includes: receiving Activate commands from a memory controller directed to specified memory locations within a first of multiple portions of memory; responsive to receipt of an Activate command, executing the Activate command at a specified memory location of the first portion, and executing a hidden refresh at a memory location in a second portion different from the first portion; and executing external refreshes from the memory controller for the first portion, where a total number of hidden refreshes and external refreshes are to satisfy a minimum number of total refreshes for the first portion during a refresh window.

In one embodiment, the refresh window comprises a refresh cycle time. In one embodiment, executing the external refreshes comprises receiving a number of external refreshes necessary to satisfy the minimum number of total refreshes after a determination of how many external refreshes are needed to satisfy the minimum number of total refreshes. In one embodiment, the external refreshes include per bank refreshes. In one embodiment, the external refreshes include all bank refreshes. In one embodiment, further comprising: determining at the memory device how many external refreshes are needed. In one embodiment, further comprising: providing an indication of the number of external refreshes needed to the memory controller. In one embodiment, providing the indication comprises storing the number of external refreshes in a register on the memory device for access by the memory controller. In one embodiment, executing the external refreshes comprises executing a number of external refreshes determined by the memory controller. In one embodiment, further comprising the memory controller: detecting a number of Activate commands sent to respective portions; and determining a number of external refreshes needed for the first portion to satisfy the minimum number of total refreshes based on the number of Activates sent to the first portion. In one embodiment, the portion comprises a bank, and wherein the memory controller includes per bank counters to detect a number of Activate commands sent to respective banks, wherein the memory controller is to send a number of all bank refreshes based on a lowest count of the per bank counters. In one embodiment, the first portion comprises a first bank of multiple banks of memory. In one embodiment, the first bank includes multiple sub-banks, and wherein executing the hidden refresh comprises executing the hidden refresh at a memory location of a different sub-bank of the first bank. In one embodiment, the memory device comprises a synchronous dynamic random access memory (SDRAM) device compatible with a dual data rate version 5 (DDR5) based standard. In one embodiment, the memory device comprises a synchronous dynamic random access memory (SDRAM) device compatible with a low power dual data rate version 5 (LPDDR5) based standard.

In one aspect, an article of manufacture comprising a computer readable storage medium having content stored thereon, which when executed results in the performance of operations to execute a method for refreshing a memory device in accordance with any embodiment of the preceding method. In one aspect, an apparatus comprising means for performing operations to execute a method for refreshing a memory device in accordance with any embodiment of the preceding method.

In one aspect, a memory controller to interface with a memory device includes: I/O (input/output) hardware to couple to the memory device, and issue commands, including Activate commands directed to specified memory locations within a first of multiple portions of memory, wherein responsive to the Activate commands the memory device is to execute the Activate command at a specified memory location of the first portion, and to execute a hidden refresh at a memory location in a second portion different from the first portion; and refresh logic to issue external refreshes to the memory device for the first portion, wherein a total number of hidden refreshes and external refreshes are to satisfy a minimum number of total refreshes for the first portion during a refresh window.

In one embodiment, the refresh window comprises a refresh cycle time. In one embodiment, the refresh logic is to issue a number of external refreshes necessary to satisfy the minimum number of total refreshes after a determination of how many external refreshes are needed to satisfy the minimum number of total refreshes. In one embodiment, the external refreshes include per bank refreshes. In one embodiment, the external refreshes include all bank refreshes. In one embodiment, the memory device is to determine how many external refreshes are needed. In one embodiment, the I/O hardware is to receive an indication of the number of external refreshes needed from the memory device. In one embodiment, further comprising: the I/O hardware to access a register of the memory device, wherein the memory device is to store the number of external refreshes in the register. In one embodiment, the refresh logic is to determine how many external refreshes are needed. In one embodiment, further comprising: detection logic to detect a number of Activate commands issued to respective portions, and to determine a number of external refreshes needed for the first portion to satisfy the minimum number of total refreshes based on the number of Activates issued to the first portion. In one embodiment, the portion comprises a bank, and wherein the detection logic includes per bank counters to detect a number of Activate commands sent to respective banks, wherein the refresh logic is to issue a number of all bank refreshes based on a lowest count of the per bank counters. In one embodiment, the first portion comprises a first bank of multiple banks of memory. In one embodiment, the first bank includes multiple sub-banks, and wherein the memory device is to execute the hidden refresh at a memory location of a different sub-bank of the first bank. In one embodiment, the memory device comprises a synchronous dynamic random access memory (SDRAM) device compatible with a dual data rate version 5 (DDR5) based standard. In one embodiment, the memory device comprises a synchronous dynamic random access memory (SDRAM) device compatible with a low power dual data rate version 5 (LPDDR5) based standard.

In one aspect, a system for memory management includes: a memory device including multiple banks, including a first of multiple portions of memory; and control logic; and a memory controller to issue commands to the memory device, including Activate commands directed to specified memory locations within the first portion; wherein, responsive to receipt of an Activate command, the control logic of the memory device to execute the Activate command at a specified memory location of the first portion, and to execute a hidden refresh at a memory location in a second portion different from the first portion; and wherein the control logic to further execute external refreshes from the memory controller for the first portion, where a total number of hidden refreshes and external refreshes are to satisfy a minimum number of total refreshes for the first portion during a refresh window.

The system of the preceding system can include any embodiment of the preceding memory controller. In one embodiment, further comprising one or more of: at least one processor communicatively coupled to the memory controller and the memory device; a display communicatively coupled to at least one processor; a battery to power the system; or a network interface communicatively coupled to at least one processor.

In one aspect, a method for interfacing with a memory device, comprising: issuing commands to the memory device, including Activate commands directed to specified memory locations within a first of multiple portions of memory, wherein responsive to the Activate commands the memory device is to execute the Activate command at a specified memory location of the first portion, and to execute a hidden refresh at a memory location in a second portion different from the first portion; and issuing external refreshes to the memory device for the first portion, wherein a total number of hidden refreshes and external refreshes are to satisfy a minimum number of total refreshes for the first portion during a refresh window.

In one embodiment, the refresh window comprises a refresh cycle time. In one embodiment, the refresh logic is to issue a number of external refreshes necessary to satisfy the minimum number of total refreshes after a determination of how many external refreshes are needed to satisfy the minimum number of total refreshes. In one embodiment, the external refreshes include per bank refreshes. In one embodiment, the external refreshes include all bank refreshes. In one embodiment, issuing the externa refreshes comprises issuing a number of external refresh as determined by the memory device. In one embodiment, further comprising: receiving an indication of the number of external refreshes needed from the memory device. In one embodiment, further comprising: accessing a register of the memory device, wherein the memory device is to store the number of external refreshes in the register. In one embodiment, further comprising: determining at the memory controller how many external refreshes are needed. In one embodiment, determining at the memory controller comprises: detecting a number of Activate commands issued to respective portions; and determining a number of external refreshes needed for the first portion to satisfy the minimum number of total refreshes based on the number of Activates issued to the first portion. In one embodiment, the portion comprises a bank, and wherein detecting the number of Activate commands issued to respective portions comprises detecting with per bank counters of the memory controller a number of Activate commands sent to respective banks, wherein issuing the external refreshes comprises issuing a number of all bank refreshes based on a lowest count of the per bank counters. In one embodiment, the first portion comprises a first bank of multiple banks of memory. In one embodiment, the first bank includes multiple sub-banks, and wherein the memory device is to execute the hidden refresh at a memory location of a different sub-bank of the first bank. In one embodiment, the memory device comprises a synchronous dynamic random access memory (SDRAM) device compatible with a dual data rate version 5 (DDR5) based standard. In one embodiment, the memory device comprises a synchronous dynamic random access memory (SDRAM) device compatible with a low power dual data rate version 5 (LPDDR5) based standard.

In one aspect, an article of manufacture comprising a computer readable storage medium having content stored thereon, which when executed results in the performance of operations to execute a method for refreshing a memory device in accordance with any embodiment of the preceding method. In one aspect, an apparatus comprising means for performing operations to execute a method for refreshing a memory device in accordance with any embodiment of the preceding method.

In one aspect, a system for memory management includes: a memory device including multiple banks, including a first bank with multiple sub-banks; and control logic; and a memory controller to issue commands to the memory device, including Activate commands directed to specified memory locations within the first bank; wherein, responsive to receipt of an Activate command, the control logic of the memory device to execute the Activate command at a specified memory location of the first bank, and to execute a hidden refresh at a memory location in a different sub-bank of the first bank; and wherein the control logic to further execute external refreshes from the memory controller for the first bank, where a total number of hidden refreshes and external refreshes are to satisfy a minimum number of total refreshes for the first bank during a refresh window.

In one embodiment, the refresh window comprises a refresh cycle time. In one embodiment, the memory controller is to issue a number of external refreshes for the first bank necessary to satisfy the minimum number of total refreshes after a determination of how many external refreshes are needed to satisfy the minimum number of total refreshes. In one embodiment, the external refreshes include per bank refreshes. In one embodiment, the external refreshes include all bank refreshes. In one embodiment, the control logic of the memory device is to determine how many external refreshes are needed. In one embodiment, the memory device is to provide an indication of the number of external refreshes needed to the memory controller. In one embodiment, the memory device further comprising: a register, wherein the control logic is to store the number of external refreshes in the register for access by the memory controller. In one embodiment, the memory controller is to determine how many external refreshes are needed. In one embodiment, the memory controller is to detect a number of Activate commands sent to respective banks, and to determine a number of external refreshes needed for the first bank to satisfy the minimum number of total refreshes based on the number of Activates sent to the first bank. In one embodiment, the memory controller includes per bank counters to detect a number of Activate commands sent to respective banks, and to send a number of all bank refreshes based on a lowest count of the per bank counters. In one embodiment, the memory device comprises a synchronous dynamic random access memory (SDRAM) device compatible with a dual data rate version 5 (DDR5) based standard. In one embodiment, the memory device comprises a synchronous dynamic random access memory (SDRAM) device compatible with a low power dual data rate version 5 (LPDDR5) based standard. In one embodiment, further comprising one or more of: at least one processor communicatively coupled to the memory controller and the memory device; a display communicatively coupled to at least one processor; a battery to power the system; or a network interface communicatively coupled to at least one processor.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware, software, or a combination. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, data, or a combination. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters or sending signals, or both, to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory device to interface in a memory subsystem, comprising:
a first of multiple portions of memory;
I/O (input/output) hardware to couple to an associated memory controller, and receive commands from the memory controller, including Activate commands directed to specified memory locations within the first portion; and
control logic internal to the memory device, responsive to receipt of an Activate command, to execute the Activate command at a specified memory location of the first portion, and to execute a hidden refresh at a memory location in a second portion different from the first portion;
wherein the control logic to further execute external refreshes from the memory controller for the first portion, where a total number of hidden refreshes and external refreshes are to satisfy a minimum number of total refreshes for the first portion during a refresh window.

2. The memory device of claim 1, wherein the I/O hardware is to receive a number of external refreshes necessary to satisfy the minimum number of total refreshes after a determination of how many external refreshes are needed to satisfy the minimum number of total refreshes.

3. The memory device of claim 2, wherein the external refreshes include per bank refreshes.

4. The memory device of claim 2, wherein the external refreshes include all bank refreshes.

5. The memory device of claim 2, wherein the control logic is to determine how many external refreshes are needed.

6. The memory device of claim 5, wherein the I/O hardware is to provide an indication of the number of external refreshes needed to the memory controller.

7. The memory device of claim 5, further comprising:
a register, wherein the control logic is to store the number of external refreshes in the register for access by the memory controller.

8. The memory device of claim 2, wherein the memory controller is to determine how many external refreshes are needed.

9. The memory device of claim 8, wherein the memory controller is to detect a number of Activate commands sent to respective portions, and to determine a number of external refreshes needed for the first portion to satisfy the minimum number of total refreshes based on the number of Activates sent to the first portion.

10. The memory device of claim 8, wherein the portion comprises a bank, and wherein the memory controller includes per bank counters to detect a number of Activate commands sent to respective banks, and to send a number of all bank refreshes based on a lowest count of the per bank counters.

11. The memory device of claim 1, wherein the first portion comprises a first bank of multiple banks of memory.

12. The memory device of claim 11, wherein the first bank includes multiple sub-banks, and wherein the control logic is to execute the hidden refresh at a memory location of a different sub-bank of the first bank.

13. The memory device of claim 1, wherein the memory device comprises a synchronous dynamic random access memory (SDRAM) device compatible with a dual data rate version 5 (DDR5) based standard.

14. The memory device of claim 1, wherein the memory device comprises a synchronous dynamic random access memory (SDRAM) device compatible with a low power dual data rate version 5 (LPDDR5) based standard.

15. A system for memory management, comprising:
a memory device including
multiple banks, including a first bank with multiple sub-banks; and
control logic; and
a memory controller to issue commands to the memory device, including Activate commands directed to specified memory locations within the first bank;
wherein, responsive to receipt of an Activate command, the control logic of the memory device to execute the Activate command at a specified memory location of the first bank, and to execute a hidden refresh at a memory location in a different sub-bank of the first bank; and
wherein the control logic to further execute external refreshes from the memory controller for the first bank, where a total number of hidden refreshes and external refreshes are to satisfy a minimum number of total refreshes for the first bank during a refresh window.

14. The system of claim 13, wherein the memory controller is to issue a number of external refreshes for the first bank necessary to satisfy the minimum number of total refreshes after a determination of how many external refreshes are needed to satisfy the minimum number of total refreshes.

15. The system of claim 14, wherein the external refreshes include per bank refreshes.

16. The system of claim 14, wherein the external refreshes include all bank refreshes.

17. The system of claim 14, wherein the control logic of the memory device is to determine how many external refreshes are needed.

18. The system of claim 17, wherein the memory device is to provide an indication of the number of external refreshes needed to the memory controller.

19. The system of claim 17, the memory device further comprising:
a register, wherein the control logic is to store the number of external refreshes in the register for access by the memory controller.

20. The system of claim 14, wherein the memory controller is to determine how many external refreshes are needed.

21. The system of claim 20, wherein the memory controller is to detect a number of Activate commands sent to respective banks, and to determine a number of external refreshes needed for the first bank to satisfy the minimum number of total refreshes based on the number of Activates sent to the first bank.

22. The system of claim 20, wherein the memory controller includes per bank counters to detect a number of Activate commands sent to respective banks, and to send a number of all bank refreshes based on a lowest count of the per bank counters.

23. The system of claim 13, wherein the memory device comprises a synchronous dynamic random access memory (SDRAM) device compatible with a dual data rate version 5 (DDR5) based standard.

24. The system of claim 13, wherein the memory device comprises a synchronous dynamic random access memory (SDRAM) device compatible with a low power dual data rate version 5 (LPDDR5) based standard.

25. The system of claim 13, further comprising one or more of:
at least one processor communicatively coupled to the memory controller and the memory device;
a display communicatively coupled to at least one processor;
a battery to power the system; or
a network interface communicatively coupled to at least one processor.
